(19) United States
(12) Patent Application Publication
(10) Pub. No.: US 2021/0028403 A1
(43) Pub. Date: Jan. 28, 2021

(54) ARRAY SUBSTRATE, METHOD FOR FABRICATING THE SAME, AND DISPLAY DEVICE

(71) Applicants: Hefei Xinsheng Optoelectrics Technology Co., Ltd., Hefei, Anhui (CN); BOE Technology Group Co., Ltd., Beijing (CN)

(72) Inventors: Wenbin JIA, Beijing (CN); Feifei ZHU, Beijing (CN); Li SUN, Beijing (CN); Xiang WAN, Beijing (CN); Zhijie YE, Beijing (CN); Xinxin WANG, Beijing (CN)

(21) Appl. No.: 16/476,465

(22) PCT Filed: Nov. 6, 2018
(86) PCT No.: PCT/CN2018/114200

§ 371 Date: Jul. 8, 2019

(30) Foreign Application Priority Data
Mar. 28, 2018 (CN) 201810265297.2

(51) Int. Cl. H01L 51/52; H01L 27/32; H01L 51/56

(52) U.S. Cl. CPC H01L 51/5271; H01L 2251/5369; H01L 51/56; H01L 27/3246

(57) ABSTRACT

This disclosure relates to the field of display technologies, and discloses an array substrate, a method for fabricating the same, and a display device. The array substrate includes: an underlying substrate; a pixel defining layer located on one side of the underlying substrate, and including a plurality of blocking walls arranged at intervals; and electroluminescent function layers each located between two adjacent blocking walls of the plurality of blocking walls. First metallic nanoparticle layers are arranged on side walls of the plurality of blocking walls proximate to the electroluminescent function layers, and are configured to reflect light exiting the electroluminescent function layers. Thus the light extraction efficiency of OLED elements can be improved.

### CROSS REFERENCE

This disclosure is a U.S. National Stage of International Application No. PCT/CN2018/114200 , filed on Nov. 6, 2018, designating the United States and claiming the priority of Chinese Patent Application No. 201810265297.2, filed with the Chinese Patent Office on Mar. 28, 2018, and entitled “a pixel structure, a method for fabricating the same, and a display device”. The entire disclosure of each of the applications above is incorporated herein by reference.

### FIELD

This disclosure relates to the field of display technologies, and particularly to an array substrate, a method for fabricating the same, and a display device.

### BACKGROUND

Organic light-emitting diodes (OLEDs), as a kind of active light-emitting elements, have attracted broad attention from academia and industry due to their potential applications in the fields of displays and illumination. In the field of displays, comparing with liquid crystal displays (LCDs), OLED display panels have advantages such as self-emitting property, fast response time, a wide viewing angle, high brightness, high color saturation, and light weight, and is widely accepted as a next-generation display technology considered to take the place of LCDs. An OLED produces light by recombination of electrons and holes in a light-emitting layer to form excitons. At present, an important factor hindering development of OLED display panels is the light extraction efficiency. Accordingly it is highly desired to improve the light extraction efficiency of OLED display panels.

### SUMMARY

An embodiment of this disclosure provides an array substrate. The array substrate includes an underlying substrate, a pixel defining layer, and electroluminescent function layers. The pixel defining layer is located on one side of the underlying substrate, and including a plurality of blocking walls arranged at intervals. Each of the electroluminescent function layers is located between two adjacent blocking walls of the plurality of blocking walls. First metallic nanoparticle layers are arranged on side walls of the plurality of blocking walls proximate to the electroluminescent function layers, and are configured to reflect light exiting the electroluminescent function layers.

According to some implementation modes of embodiment of the disclosure, the first metallic nanoparticle layers include metallic reflection spherical nanoparticles.

According to some implementation modes of embodiment of the disclosure, sizes of each of the metallic reflection spherical nanoparticles range from 10 nm to 20 nm.

According to some implementation modes of embodiment of the disclosure, the array substrate further includes first electrodes located between the electroluminescent function layers and the underlying substrate, and second electrodes located on sides of the electroluminescent function layers away from the underlying substrate.

According to some implementation modes of embodiment of the disclosure, the first electrodes are reflection electrodes, and the second electrodes are transparent electrodes.

According to some implementation modes of embodiment of the disclosure, the array substrate further includes second metallic nanoparticle layers located between the first electrodes and the electroluminescent function layers. The second metallic nanoparticle layers are configured to reflect the light exiting the electroluminescent function layers.

According to some implementation modes of embodiment of the disclosure, the first electrodes are transparent electrodes, and the second electrodes are reflection electrodes.

According to some implementation modes of embodiment of the disclosure, the array substrate further includes third metallic nanoparticle layers located between the second electrodes and the electroluminescent function layers. The third metallic nanoparticle layers are configured to reflect the light exiting the electroluminescent function layers.

According to some implementation modes of embodiment of the disclosure, material of the second metallic nanoparticle layers is the same as material of the first metallic nanoparticle layers.

According to some implementation modes of embodiment of the disclosure, material of the third metallic nanoparticle layers is the same as the material of the first metallic nanoparticle layers.

An embodiment of the disclosure also provides a display device. The display device includes the array substrate according to any one of the implementations above.

An embodiment of the disclosure provides a method for fabricating the array substrate according to the embodiment above. The method includes: forming the pixel defining layer on one side of the underlying substrate, where the pixel defining layer includes the plurality of blocking walls arranged at intervals; forming the first metallic nanoparticle layers on the side walls of the plurality of blocking walls; and forming the electroluminescent function layers each located between two adjacent blocking walls of the plurality of blocking walls. The first metallic nanoparticle layers are located on the side walls of the plurality of blocking walls proximate to the electroluminescent function layers, and are configured to reflect light exiting the electroluminescent function layers.

According to some implementation modes of the embodiment of the disclosure, forming the first metallic nanoparticle layers on the side walls of the blocking walls includes: printing solution including first metallic nanoparticles onto the side walls of the blocking walls using an inkjet printing process to form the first metallic nanoparticle layers.

According to some implementation modes of embodiment of the disclosure, forming the first metallic nanoparticle layers on the side walls of the blocking walls includes: immersing the blocking walls of the pixel defining layer into solution including first metallic nanoparticles to form the first metallic nanoparticle layers, where the blocking walls are upside down when they are immersed into the solution.

According to some implementation modes of embodiment of the disclosure, for each of the blocking walls, a depth of a part of the blocking wall immersed into the solution is shallower than a depth of the blocking wall.

According to some implementation modes of embodiment of the disclosure, forming the pixel defining layer on one side of the underlying substrate, and forming the first metallic nanoparticle layers on the side walls of the blocking walls includes: forming a pixel defining layer film doped with first metallic nanoparticles on the underlying substrate; forming the pixel defining layer including the plurality of blocking walls arranged at intervals, and forming the first metallic nanoparticle layers on the side walls of the blocking walls, after the pixel defining layer film is exposed and developed.

According to some implementation modes of embodiment of the disclosure, before the pixel defining layer is formed on one side of the underlying substrate, the method further includes: forming first electrodes on the underlying substrate. And after the electroluminescent function layers are formed, the method further includes: forming second electrodes on the underlying substrate formed with the electroluminescent function layers.

### BRIEF DESCRIPTION OF THE DRAWINGS

The drawings herein are incorporated into the specification, constitute a part of the specification, illustrate embodiments of this disclosure, and serve together with the description to set forth principles of this disclosure. Apparently the drawings to be described below illustrate only a part but not all of the embodiments of this disclosure, and those having ordinary skill in the art can obtain other drawings according to these drawings without making any inventive effort.

FIG. 1 illustrates a schematic diagram of a structure of an array substrate in the related art.

FIG. 2 illustrates a first schematic diagram of a structure of an array substrate according to an implementation mode of an embodiment of this disclosure.

FIG. 3 illustrates a second schematic diagram of the structure of the array substrate according to another implementation mode of the embodiment of this disclosure.

FIG. 4 illustrates a third schematic diagram of the structure of the array substrate according to still another implementation mode of the embodiment of this disclosure.

FIG. 5 illustrates a flow chart of a method for fabricating an array substrate according to an embodiment of this disclosure.

### DETAILED DESCRIPTION OF THE EMBODIMENTS

Exemplary implementation modes of embodiments of this disclosure will be described below in further details with reference to the drawings. However, the embodiments can be implemented in various implementation modes which shall not be construed as being limited to the examples herein. On the contrary, these implementation modes are provided to make this disclosure more comprehensive and complete, and to convey the conception of the embodiments to those skilled in the art. The features, structures, or characteristics described herein can be combined in one or more implementation modes when appropriate.

Moreover, the drawings are only schematically illustrative of this disclosure, but are not necessarily drawn to scale. The similar reference numerals throughout the drawings will refer to like or similar components, so a repeated description thereof will be omitted herein. Some blocks as illustrated by the drawings refer to functional entities, and does not necessarily correspond to physically or logically separate entities. These functional entities can be embodied in a software form, or can be embodied in one or more hardware modules or integrated circuits, or can be embodied in different networks and/or processor devices and/or micro-controller devices.

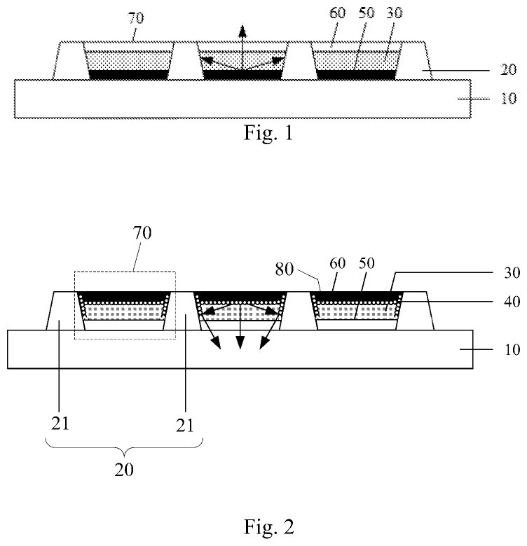

The OLED has attracted broad attention from industry as an active light-emitting element and the light extraction efficiency thereof is an important factor impacting the OLED. As illustrated by FIG. 1, a part of light generated by a light-emitting layer 30 is propagated in a traverse or oblique direction and is absorbed by a pixel defining layer 20. Another part of the light is quenched on a metallic interface, e.g., a surface of an anode (a pixel electrode 50, e.g., a metal anode, of a top-emitting OLED element). Only a remaining part of the light can exit normally, so it is highly desired to improve the light extraction efficiency of the OLED.

In the related art, in order to improve the light extraction efficiency of the OLED, a metallic reflection face is formed on an opening side wall of the pixel defining layer, i.e., a side thereof for arranging the light-emitting layer. However, a process of forming the metallic reflection face is complicated. For example, the pixel defining layer shall cover a part of the anode while the metallic reflection face shall not touch the anode. On the other hand, surface curvature of the metallic reflection face is limited, leading to a still limited light extraction efficiency of the element. For example, reflected light tends to be quenched on the surface of the metallic reflection face.

An embodiment of this disclosure provides an array substrate applicable to a bottom-emitting OLED display panel, a top-emitting OLED display panel, and a bidirectional OLED display panel. As illustrated by FIG. 2 to FIG. 4, the array substrate can include an underlying substrate 10, a pixel defining layer 20, and electroluminescent function layers 30. The pixel defining layer 20 is located on one side of the underlying substrate 10, and includes a plurality of blocking walls 21 arranged at intervals, with openings 70 in between. Each of the electroluminescent function layers 30 are located between two adjacent blocking walls 21 of the plurality of blocking walls 21, that is, the electroluminescent function layers 30 are located in the openings 70 on a side of the pixel defining layer 20 away from the underlying substrate 10. First metallic nanoparticle layers 40 are arranged on side walls of the blocking walls 21, and the side walls where the first metallic nanoparticle layers 40 are arranged are proximate to the electroluminescent function layers 30. The first metallic nanoparticle layers 40 are configured to reflect light exiting the electroluminescent function layers 30. The openings 70 correspond to pixel areas of the array substrate, and the first metallic nanoparticle layers 40 are distributed on the surfaces of the side walls of the blocking walls 21 of the pixel defining layer 20.

In the array substrate according to the embodiment of this disclosure, the first metallic nanoparticle layers configured to reflect the light exiting the electroluminescent function layers are arranged on the side walls of the blocking walls of the pixel defining layer 20, so that light rays incident on the pixel defining layer 20 in a traverse or oblique direction can be reflected back to and propagated out of the pixel areas, thus improving the light extraction efficiency of the array substrate.

It shall be noted that the first metallic nanoparticles in the first metallic nanoparticle layer refer to nanoscale particles having a surface with a reflection property. The shape of a first metallic nanoparticle can be a sphere, a quasi-sphere, a nano-size rod, a nano-size sheet, and etc., although the embodiment of this disclosure is limited thereto. Furthermore, as illustrated by FIG. 2 to FIG. 4, according to some implementation modes of the embodiment of this disclosure, the first metallic nanoparticles in the first metallic nanoparticle layer can include metallic reflection spherical nanoparticles, but the embodiment of this disclosure is not limited thereto, and any nanoparticles having a reflection property are applicable. According to some implementation modes of the embodiment of the disclosure, the metallic reflection spherical nanoparticles are evenly distributed on the surfaces of the side walls of the blocking walls 21 of the pixel defining layer 20 for a good effect of reflecting the light rays.

According to some implementation modes of the embodiment of the disclosure, sizes of each of the metallic reflection spherical nanoparticles are between 10 nm and 20 nm, for example, so that a process of forming the spherical particles can be simplified, but also a better effect of reflecting the light can be achieved. For example, the sizes of the metallic reflection spherical nanoparticles can be 10 nm, 15 nm, or 20 nm. Of course, in a real application, the sizes of the metallic reflection spherical nanoparticles can be determined according to a real application environment, although the embodiment of this disclosure is not limited thereto.

In some implementation modes, the electroluminescent function layer can include electroluminescent function layers. According to some implementation modes of the embodiment of this disclosure, the array substrate can further include first electrodes 50 located between the electroluminescent function layers 30 and the underlying substrate 10, and second electrodes 60 located on sides of the electroluminescent function layers 30 away from the underlying substrate 10 so that elements in the pixel areas can be OLED elements. Furthermore, an important factor hindering the development of an OLED element is the service life thereof, which is determined by density of a current driving the OLED to emit light. If brightness of light emitted by the OLED is fixed, then the service life thereof can be extended by enhancing the light extraction efficiency thereof, and lowering the current density thereof. According to the embodiment of this disclosure, the first metallic nanoparticle layers are arranged on the side walls of the blocking walls of the pixel defining layer 20 so that the light rays incident on the pixel defining layer 20 in a traverse or oblique direction can be reflected back to and exit the pixel area, thus improving the light extraction efficiency of the OLED elements, so the driving current can be lowered for the same brightness to lower power consumption, and extend the service life of the OLED elements. It shall be noted that a pixel circuit configured to drive the electroluminescent function layers to emit light is formed on the underlying substrate according to some implementation modes of the embodiment of this disclosure, where the pixel circuit includes an array of thin film transistors (TFTs).

According to some implementation modes of the embodiment of this disclosure, the first electrodes 50 can be anodes and the second electrodes 60 can be cathodes. Or, the first electrodes 50 can be cathodes and the second electrodes 60 can be anodes. For each of the electroluminescent function layers 30, the electroluminescent function layer 30 can include an electron injection layer, an electron transport layer, an electroluminescent material layer, a hole transport layer, and a hole injection layer, which are superimposed in this order from a cathode to an anode. In generally, the electron injection layers, the electron transport layers, the hole transport layers, and the hole injection layers are formed to cover the entire underlying substrate, so the first metallic nanoparticle layers and the second electrodes 60 do not touch. Furthermore, the first metallic nanoparticle layers can be arranged on parts of the side walls of the blocking walls of the pixel defining layers which are between the electroluminescent material layers and the blocking walls of the pixel defining layers.

According to some implementation modes of the embodiment of the disclosure, such as what is illustrated by FIG. 2, in the bottom-emitting OLED display panel, the first electrodes 50 can be transparent electrodes, that is, light can be transmitted outwards through the first electrodes 50. The second electrodes 60 can be reflection electrodes, that is, the second electrodes 60 can reflect light. Accordingly, the array substrate can be a bottom-emitting OLED array substrate. Furthermore, in order to improve the light extraction efficiency, the array substrate can further include third metallic nanoparticle layers 80 located between the second electrodes 60 and the electroluminescent function layers 30, where the third metallic nanoparticle layers are configured to reflect the light emitted from the electroluminescent function layers 30. Since the third metallic nanoparticle layers 80 can reflect the light emitted towards the second electrodes 60, the light extraction efficiency can be further improved. Furthermore, material of the third metallic nanoparticle layers can be the same as material of the first metallic nanoparticle layers, that is, third metallic nanoparticles in the third metallic nanoparticle layers are the same as the first metallic nanoparticles in the first metallic nanoparticle layers. For example, the third and first metallic nanoparticles can be metallic reflection spherical nanoparticles. Accordingly the first metallic nanoparticle layers and the third metallic nanoparticle layers can be made by using the same material.

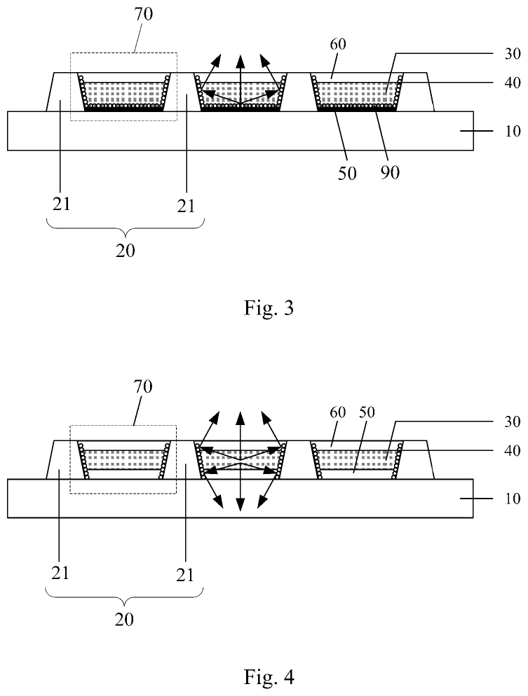

According to some implementation modes of the embodiment of the disclosure, such as what is illustrated by FIG. 3, in the top-emitting OLED display panel, the second electrodes 60 can be transparent electrodes, and the first electrodes 50 can be reflection electrodes, so that the array substrate can be a top-emitting OLED array substrate. Furthermore, in order to improve the light extraction efficiency, the array substrate can further include electrode reflection thin films located between the first electrodes and the electroluminescent function layers. Or the array substrate can further include second metallic nanoparticle layers 90 located between the first electrodes 50 and the electroluminescent function layers 30, where the second metallic nanoparticle layers 90 are configured to reflect the light emitted from the electroluminescent function layers 30 so that the second metallic nanoparticle layers 90 can reflect the light emitted towards the first electrodes 50 to further improve the light extraction efficiency. Furthermore, there are the second metallic nanoparticle layers 90 on the surfaces of the first electrodes 50, so the light in the top-emitting OLED array substrate can be significantly alleviated from being quenched, to further improve the light out-coupling efficiency of the OLED elements. Furthermore, the first electrodes 50 and the second metallic nanoparticle layers 90 together can be anodes. Moreover, material of the second metallic nanoparticle layers can be the same as the material of the first metallic nanoparticle layers. That is, second metallic nanoparticles in the second metallic nanoparticle layers are the same as the first metallic nanoparticles in the first metallic nanoparticle layers. For example, the first and second metallic nanoparticles can be metallic reflection spherical nanoparticles, so that the first metallic nanoparticle layers and the second metallic nanoparticle layers can be made of the same material.

According to some implementation modes of the embodiment of the disclosure, such as what is illustrated by FIG. 4, in the bidirectional OLED display panel, the first electrodes 50 and the second electrodes 60 can be transparent electrodes, Since the first metallic nanoparticle layers are arranged on the surfaces of the side walls of the blocking walls 21 of the pixel defining layer 20, the surfaces of the side walls of the blocking walls 21 of the pixel defining layer 20 have reflection effects.

Based upon the same inventive conception, an embodiment of this disclosure further provides a display device including the array substrate according to any one of implementation modes of the above-mentioned embodiment of this disclosure. The display device can address the problem under a similar principle to the array substrate above, so reference can be made to the implementation of the array substrate above for implementation of the display device, and a repeated description thereof is omitted herein.

According to some implementation modes of the embodiment, the display device can be any product or component having a display function, such as a mobile phone, a tablet computer, a TV set, a monitor, a laptop computer, a digital photo frame, or a navigator. All other components indispensable to the display device shall readily occur to those ordinarily skilled, so a repeated description thereof is omitted herein, and the embodiment of this disclosure is not limited thereto.

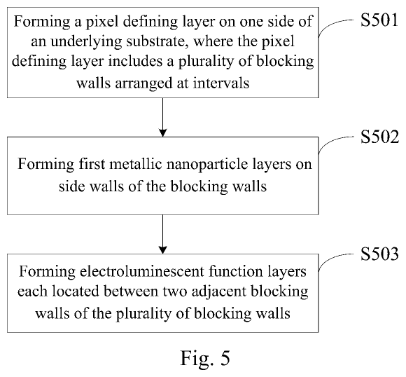

Based upon the same inventive conception, an embodiment of this disclosure further provides a method for fabricating an array substrate. As illustrated by FIG. 5, the method can include the following operations S501-S503.

The operation S501 is: forming a pixel defining layer on one side of an underlying substrate, where the pixel defining layer includes a plurality of blocking walls arranged at intervals.

The operation S502 is: forming first metallic nanoparticle layers on side walls of the blocking walls.

The operation S503 is: forming electroluminescent function layers each located between two adjacent blocking walls of the plurality of blocking walls, where the first metallic nanoparticle layers are located on the side walls of the plurality of blocking walls proximate to the electroluminescent function layers, and are configured to reflect light exiting the electroluminescent function layers.

First metallic nanoparticles in the first metallic nanoparticle layer refer to nanoscale particles having a surface with a reflection property. The shape of a first metallic nanoparticle can be a sphere, a quasi-sphere, a nano-size rod, a nano-size sheet, and etc., although the embodiment of this disclosure is limited thereto. Furthermore, as illustrated by FIG. 2 to FIG. 4, according to some implementation modes of the embodiment of this disclosure, the first metallic nanoparticles in the first metallic nanoparticle layer can include metallic reflection spherical nanoparticles, but the embodiment of this disclosure is not limited thereto, and any nanoparticles having a reflection property are applicable. According to some implementation modes of the embodiment of the disclosure, the metallic reflection spherical nanoparticles are evenly distributed on the surfaces of the side walls of the blocking walls 21 of the pixel defining layer 20 for a good effect of reflecting the light rays.

According to some implementation modes of the embodiment of the disclosure, sizes of each of the metallic reflection spherical nanoparticles are between 10 nm and 20 nm, for example, so that a process of forming the spherical particles can be simplified, but also a better effect of reflecting the light can be achieved. For example, the sizes of the metallic reflection spherical nanoparticles can be 10 nm, 15 nm, or 20 nm. Of course, in a real application, the sizes of the metallic reflection spherical nanoparticles can be determined according to a real application environment, although the embodiment of this disclosure is not limited thereto.

In the method for fabricating the array substrate according to the embodiment of this disclosure, the first metallic nanoparticle layers able to reflect the light emitted from the electroluminescent function layers are formed on the side walls of the blocking walls of the pixel defining layer 20, so that light rays incident on the pixel defining layer 20 in a traverse or oblique direction can be reflected back to and propagated out of pixel areas, thus improving the light extraction efficiency of OLED elements in the array substrate. Accordingly, the driving current at the same brightness can be lowered to lower power consumption and extend the service life of the OLED elements.

According to some implementation modes of this embodiment, before the pixel defining layer including a plurality of openings is formed on one side of the underlying substrate, the method can further include forming first electrodes on the underlying substrate; and after the electroluminescent function layers are formed in the openings, the method can further include forming second electrodes on the underlying substrate formed with the electroluminescent function layers. According to some implementation modes of the embodiment, transparent electrically-conductive layers can be formed on the underlying substrate as the first electrodes, and reflection electrically-conductive layers can be formed on the underlying substrate formed with the electroluminescent function layers as the second electrodes. Accordingly, a bottom-emitting OLED array substrate is formed. Or, reflection electrically-conductive layers can be formed on the underlying substrate as the first electrodes, and transparent electrically-conductive layers can be formed on the underlying substrate formed with the electroluminescent function layers as the second electrodes. Accordingly a top-emitting OLED array substrate is formed.

According to some implementation modes of this embodiment, the first metallic nanoparticle layers can be formed on the side walls of the blocking walls by printing solution including the first metallic nanoparticles on the side walls of the blocking walls using an inkjet printing process to form the first metallic nanoparticle layers. For example, the material of the first metallic nanoparticle layers is metallic reflection spherical nanoparticles, and the metallic reflection spherical nanoparticles on the surfaces of the side walls of the blocking walls 21 of the pixel defining layer 20 facing the electroluminescent function layers 30 can be formed by forming the pixel defining layer 20 for filling the electroluminescent function layers 30 on the underlying substrate 10, and printing solution including metallic reflection spherical nanoparticles on the surfaces of the side walls of the blocking walls 21 of the pixel defining layer 20 facing the electroluminescent function layers 30 using an inkjet printing process. Then the metallic reflection spherical nanoparticles are distributed on the surfaces of the side walls of the blocking walls 21 of the pixel defining layer 20. The metallic reflection spherical nanoparticles formed by printing the solution can be the same as the metallic reflection spherical nanoparticles in the solution, or can be metallic reflection spherical nanoparticles obtained by treating the metallic reflection spherical nanoparticles in the solution, thus having a different size or a different shape from the original metallic reflection spherical nanoparticles.

According to some other implementation modes of this embodiment, the first metallic nanoparticle layers can be formed using a self-assembling method. The first metallic nanoparticle layers can be formed on the side walls of the blocking walls by immersing the blocking walls of the pixel defining layer into solution comprising first metallic nanoparticles to form the first metallic nanoparticle layers, where the blocking walls are upside down, i.e., the blocking walls are under the underlying substrate, when they are immersed into the solution. For example, the material of the first metallic nanoparticle layers is metallic reflection spherical nanoparticles. The metallic reflection spherical nanoparticles on the surfaces of the side walls of the blocking walls 21 of the pixel defining layer 20 facing the electroluminescent function layers 30 can be formed by forming the pixel defining layer 20 for filling the electroluminescent function layers 30 on the underlying substrate 10, turning the underlying substrate formed with the pixel defining layer 20 upside down, and immersing the upside down underlying substrate into solution including the metallic reflection spherical nanoparticles. Then the metallic reflection spherical nanoparticles are distributed on the surfaces of the side walls of the blocking walls 21 of the pixel defining layer 20. In the case of the top-emitting OLED display panel, the underlying substrate formed with the pixel defining layer 20 can be immersed into the solution including the metallic reflection spherical nanoparticles. In the case of the bottom-emitting OLED display panel, light shall be transmitted outwards through the first electrodes, so the first electrodes shall not be immersed into or contact the solution when the underlying substrate is upside down, and only the blocking walls 21 of the pixel defining layer 20 are turned upside down, and immersed into the solution including the metallic reflection spherical nanoparticles. Furthermore, for each of the blocking walls, a depth of a part of the blocking wall which is immersed into the solution is shallower than a depth of the blocking walls, so that the solution and the first electrodes do not touch.

According to still some other implementation modes of this embodiment, the first metallic nanoparticle layers can alternatively be formed through exposure. Forming the pixel defining layer on one side of the underlying substrate, and forming the first metallic nanoparticle layers on the side walls of the blocking walls by: forming a pixel defining layer film doped with the first metallic nanoparticles on the underlying substrate; and after the pixel defining layer film is exposed and developed, forming the pixel defining layer comprising the plurality of blocking walls arranged at intervals, and forming the first metallic nanoparticle layers on the side walls of the blocking walls. For example, the material of the first metallic nanoparticle layers is metallic reflection spherical nanoparticles. The metallic reflection spherical nanoparticles on the side walls of the blocking walls 21 can be formed by forming the pixel defining layer film doped with metallic reflection spherical nanoparticles on the underlying substrate 10, and exposing and developing the pixel defining layer film to form the pixel defining layer 20 having metallic reflection spherical nanoparticles above its surface so that the metallic reflection spherical nanoparticles are formed on the side walls of the blocking walls 21 of the pixel defining layer 20, and the metallic reflection spherical nanoparticles are structured integral to the pixel defining layer 20.

As can be apparent from the implementation modes above, the method for fabricating the OLED array substrate according to the embodiment of this disclosure can form the metallic reflection spherical nanoparticles in a simple and feasible process to significantly improve the light extraction efficiency of the OLED elements.

According to some implementation modes of the embodiment of the disclosure, such as what is illustrated by FIG. 2, in the bottom-emitting OLED display panel, after the electroluminescent function layers are formed, and before the second electrodes are formed, the method can further include forming third metallic nanoparticle layers on the electroluminescent function layers. For example, the material of the third metallic nanoparticle layers is metallic reflection spherical nanoparticles. Then the third metallic nanoparticle layers on sides of the electroluminescent function layers away from the underlying substrate can be formed before the pixel defining layer 20 is formed, and after the electroluminescent function layers are formed on the underlying substrate 10. For example, the third metallic nanoparticle layers can be formed by using an inkjet printing process or a photolithograph process. Or the underlying substrate can be immersed into solution including metallic reflection spherical nanoparticles, and the metallic reflection spherical nanoparticles can be formed on the electroluminescent function layers.

According to some implementation modes of the embodiment of the disclosure, such as what is illustrated by FIG. 3, in the top-emitting OLED display panel, after the first electrodes are formed, and before the electroluminescent function layers are formed, the method can further include forming second metallic nanoparticle layers on the first electrodes. For example, the material of the second metallic nanoparticle layers is metallic reflection spherical nanoparticles. The second metallic nanoparticle layers can be formed by: forming the first electrodes on the underlying substrate 10 before the pixel defining layer 20 is formed, and forming the second metallic nanoparticle layers on sides of the first electrodes away from the underlying substrate while forming the first metallic nanoparticle layers. For example, the second metallic nanoparticle layers can be formed by using an inkjet printing process or a photolithograph process. Or the underlying substrate can be immersed into solution including metallic reflection spherical nanoparticles, and the metallic reflection spherical nanoparticles can be formed on the first electrodes.

According to another implementation mode of the embodiment of this disclosure, before the pixel defining layer 20 is formed, and the first electrodes are formed on the underlying substrate 10. Then the pixel defining layer 20 including the blocking walls is formed, after which the underlying substrate 10 including the first electrodes and the pixel defining layer 20 is immersed into solution including metallic reflection spherical nanoparticles to form the metallic reflection spherical nanoparticles on the sides of the first electrodes away from the underlying substrate, and to form the metallic reflection spherical nanoparticles on the side walls of the blocking walls 21 of the pixel defining layer 20. In this way, the treatment processes can be further simplified to lower the cost.

Since the metallic reflection spherical nanoparticles are formed on the surfaces of the first electrodes 50, the light in the top-emitting OLED display panel can be significantly alleviated from being quenched, to further improve the light out-coupling efficiency of the OLED elements. It shall be noted that the second metallic nanoparticle layers can be formed similarly to the first metallic nanoparticle layers, so a repeated description thereof is omitted herein.

According to some implementation modes of the embodiment, as illustrated by FIG. 4, in the bidirectional OLED display panel, the first electrodes 50 and the second electrodes 60 can be transparent electrodes. Since the first metallic nanoparticle layers are arranged on the surfaces of the side walls of the blocking walls of the pixel defining layer 20, only the surfaces of the side walls of the blocking walls of the pixel defining layer 20 have a reflection effect.

The process for fabricating the array substrate will be described below in detail taking the top-emitting OLED display panel and the bottom-emitting OLED display panel respectively as examples.

According to some possible implementation modes of the embodiment of the disclosure, as illustrated by FIG. 2, a method for fabricating the array substrate of the bottom-emitting OLED display panel can include the following operations: forming a pixel circuit on the underlying substrate 10; forming the first electrodes 50, e.g., transparent anodes, on the underlying substrate 10; spin-coating a pixel defining layer film having a thickness of 1 μm to 1.5 μm on the underlying substrate formed with the first electrodes 50, and exposing and developing the pixel defining layer film to form the pixel defining layer 20 including pixels; printing solution including metallic reflection spherical nanoparticles on the surfaces of the side walls of the blocking walls 21 of the pixel defining layers 20 by using an inkjet printing process to form the first metallic nanoparticle layers 40 including metallic reflection spherical nanoparticles; forming the electroluminescent function layers 30 between the blocking walls 21 of the pixel defining layer 20 formed with the first metallic nanoparticle layers 40 by using a vapor-plating process or an inkjet printing process; printing solution including the metallic reflection spherical nanoparticles on surfaces of the electroluminescent function layers 30 in an inkjet printing process to form the third metallic nanoparticle layers 80 including metallic reflection spherical nanoparticles; and forming the second electrodes 60, e.g., reflection cathodes, on the electroluminescent function layers 30, thus forming the array substrate in the bottom-emitting OLED display panel.

According to some other implementation modes of the embodiment of the disclosure, as illustrated by FIG. 2, a method for fabricating the array substrate in the bottom-emitting OLED display panel can include the following operations.

Operation 1: forming a pixel circuit on the underlying substrate 10.

Operation 2: forming the first electrodes 50, e.g., transparent anodes, on the underlying substrate 10.

Operation 3: spin-coating a pixel defining layer film having a thickness of 1 μm to 1.5 μm on the underlying substrate formed with the first electrodes 50, and exposing and developing the pixel defining layer film to form the pixel defining layer 20 including pixels. The underlying substrate formed with the pixel defining layer 20 is immersed into solution including metallic reflection spherical nanoparticles in an upside down state while the first electrodes 50 is prevented from being immersed into the solution, to form evenly distributed metallic reflection spherical nanoparticles on the surfaces of the side walls of the blocking walls of the pixel defining layer 20 by using the self-assembling method, thereby forming the first metallic nanoparticle layers. The evenly distributed metallic reflection spherical nanoparticles can be formed by controlling temperature and concentration of the solution as long as density of the solution is uniform and the pixel defining layer 20 is immersed in the solution for a sufficiently long period of time. When the evenly distributed metallic reflection spherical nanoparticles are formed on the surfaces of the side walls of the blocking walls of the pixel defining layer 20, metallic reflection spherical nanoparticles may occur on the surface of the pixel defining layer 20, but no leakage current would occur from any side as long as these metallic reflection spherical nanoparticles are discrete.

Operation 4: forming the electroluminescent function layers 30 between the blocking walls 21 of the pixel defining layer 20 formed with the first metallic nanoparticle layers 40 by using a vapor-plating process or an inkjet printing process.

Operation 5: printing solution including metallic reflection spherical nanoparticles on the surfaces of the electroluminescent function layers 30 by using an inkjet printing process to form the third metallic nanoparticle layers 80 including metallic reflection spherical nanoparticles.

Operation 6: forming the second electrodes 60, e.g., reflection cathodes, on the electroluminescent function layers 30, to form the array substrate in the bottom-emitting OLED display panel.

According to still some other implementation modes of the embodiment, as illustrated by FIG. 2, a method for fabricating the array substrate in the bottom-emitting OLED display panel can include the following operations: forming a pixel circuit on the underlying substrate 10; forming the first electrodes 50, e.g., transparent anodes, on the underlying substrate 10; spin-coating a pixel defining layer film having a thickness of 1 μm to 1.5 μm and doped with metallic reflection spherical nanoparticles on the underlying substrate formed with the first electrodes 50, and exposing and developing the pixel defining layer film to form the pixel defining layer 20 including pixels with the metallic reflection spherical nanoparticles above surface of the pixel defining layer 20; forming the electroluminescent function layers 30 between the blocking walls 21 of the pixel defining layer 20 formed with first metallic nanoparticle layers by a vapor-plating process or an inkjet printing process; printing solution including metallic reflection spherical nanoparticles on the surfaces of the electroluminescent function layers 30 by using an inkjet printing process to form the third metallic nanoparticle layers 80 including metallic reflection spherical nanoparticles; and forming the second electrodes 60, e.g., reflection cathodes, on the electroluminescent function layers 30, to form the array substrate in the bottom-emitting OLED display panel.

According to some implementation modes of the embodiment, as illustrated by FIG. 3, a method for fabricating the array substrate in the top-emitting OLED display panel can include the following operations: forming a pixel circuit on the underlying substrate 10; forming the first electrodes 50, e.g., reflection anodes, on the underlying substrate 10, where the reflection anodes can be formed by firstly forming electrically-conductive layers of, e.g., Ag/ITO, through spraying in this operation; spin-coating a pixel defining layer film having a thickness of 1 μm to 1.5 μm on the underlying substrate formed with the first electrodes 50, and exposing and developing the pixel defining layer film to form the pixel defining layers 20 including pixels; printing solution including metallic reflection spherical nanoparticles on the first electrodes 50 and the surfaces of the side walls of the blocking walls 21 of the pixel defining layers 20 by using an inkjet printing process to form the first metallic nanoparticle layers 40 and the second metallic nanoparticle layers 90 each including metallic reflection spherical nanoparticles; and forming the electroluminescent function layers 30 between the blocking walls 21 of the pixel defining layer 20 by using a vapor-plating process or an inkjet printing process, and forming the second electrodes 60, e.g., transparent cathodes, above the electroluminescent function layers 30, to form the array substrate in the top-emitting OLED display panel.

According to some implementation modes of the embodiment, as illustrated by FIG. 3, a method for fabricating the array substrate in the top-emitting OLED display panel can include the following operations.

Operation 1: forming a pixel circuit on the underlying substrate 10.

Operation 2: forming the first electrodes 50, e.g., reflection anodes, on the underlying substrate 10, where the reflection anodes can be formed by firstly forming electrically-conductive layers of, e.g., Ag/ITO, through spraying in this operation.

Operation 3: spin-coating a pixel defining layer film having a thickness of 1 μm to 1.5 μm on the underlying substrate formed with the first electrodes 50, and exposing and developing the pixel defining layer film to form the pixel defining layers 20 including pixels.

Operation 4: immersing the underlying substrate formed with the pixel defining layer 20 into solution including metallic reflection spherical nanoparticles when the underlying substrate is upside down or right-side-up by using the self-assembling method, and making sure that the first electrodes 50 are immersed into the solution, to form evenly distributed metallic reflection spherical nanoparticles on the first electrodes 50 and on the surfaces of the side walls of the blocking walls 21 of the pixel defining layer 20 by using the self-assembling method, thereby forming the first metallic nanoparticle layers 40 and the second metallic nanoparticle layers 90 including the metallic reflection spherical nanoparticles. Where the evenly distributed metallic reflection spherical nanoparticles can be formed by controlling temperature and concentration of the solution as long as density of the solution is uniform and the underlying substrate is immersed in the solution for a sufficiently long period of time.

Operation 5: forming the electroluminescent function layers 30 between the blocking walls 21 of the pixel defining layer 20 by using a vapor-plating process or an inkjet printing process, and forming the second electrodes 60, e.g., transparent cathodes, above the electroluminescent function layers 30, to form the array substrate of the top-emitting OLED display panel.

According to still some other implementation modes of the embodiment, a method for fabricating the array substrate in the top-emitting OLED display panel can include the following operations: forming a pixel circuit on the underlying substrate 10; forming the first electrodes 50, e.g., reflection anodes, on the underlying substrate 10, where the reflection anodes can be formed by forming electrically-conductive layers and electrode reflection thin films of, e.g., Ag/ITO, on sides of the electrically-conductive layers away from the underlying substrate 10, through spraying; spin-coating a pixel defining layer film having a thickness of 1 μm to 1.5 μm and doped with metallic reflection spherical nanoparticles on the underlying substrate formed with the first electrodes 50, and exposing and developing the pixel defining layer film to form the pixel defining layer 20 including pixels with the metallic reflection spherical nanoparticles above surface of the pixel defining layer 20; and forming the electroluminescent function layers 30 between the blocking walls 21 of the pixel defining layer 20 by using a vapor-plating process or an inkjet printing process, and forming the second electrodes 60, e.g., transparent cathodes, above the electroluminescent function layers 30, to form the array substrate in the top-emitting OLED display panel.

It shall be noted that the process for fabricating the array substrate according to the embodiment of this disclosure is not limited to the implementation modes above, and any method that can form the metallic reflection spherical nanoparticles on the surfaces of the side walls of the blocking walls of the pixel defining layer 20 falls within the protection scope of this disclosure.

It shall be noted that although several modules or units in the device have been discussed in the detailed description above, the device may not necessarily be divided into those modules or units. In fact, features or functions of two or more of the modules or units above may be embodied in one module or unit. On the contrary, features and functions of one of the modules or units above may further be divided into a plurality of modules or units.

Although the respective operations of the method according to the embodiment of this disclosure have been described with reference to the drawings in a specific order, this shall not require or suggest that these operations be performed in the specific order, or all of the operations be performed for a desirable result. Additionally or alternatively, some of the operations may be omitted, or more than one of the operations may be combined into one operation, and/or one of the operations may be decomposed into more than one operation to be executed.

Other embodiments of this disclosure shall readily occur to those skilled in the art upon considering the specification, and practicing this disclosure as described herein. This disclosure is intended to encompass any variations, uses, or adaptations of this disclosure, and all these variations, uses, or adaptations shall comply with the general principle of this disclosure, and encompass well-known knowledge or common technical means in the art which are not recited in the disclosure. The description and the embodiments are only illustrative of this disclosure, but the true scope and spirit of this disclosure shall be as defined in the appended claims.

Evidently those having ordinal skill in the art can make various modifications and variations to this disclosure without departing from the spirit and scope of this disclosure. Thus this disclosure is also intended to encompass these modifications and variations thereto so long as the modifications and variations come into the scope of the claims appended to this disclosure and their equivalents.

1. An array substrate, comprising:
an underlying substrate;
a pixel defining layer located on one side of the underlying substrate, and comprising a plurality of blocking walls arranged at intervals; and
electroluminescent function layers, each located between two adjacent blocking walls of the plurality of blocking walls, wherein,
first metallic nanoparticle layers are arranged on side walls of the plurality of blocking walls proximate to the electroluminescent function layers, and are configured to reflect light exiting the electroluminescent function layers.

2. The array substrate according to claim 1, wherein the first metallic nanoparticle layers comprise metallic reflection spherical nanoparticles.

3. The array substrate according to claim 2, wherein sizes of each of the metallic reflection spherical nanoparticles range from 10 nm to 20 nm.

4. The array substrate according to claim 1, further comprising:
first electrodes located between the electroluminescent function layers and the underlying substrate; and
second electrodes located on sides of the electroluminescent function layers away from the underlying substrate.

5. The array substrate according to claim 4, wherein the first electrodes are reflection electrodes, and the second electrodes are transparent electrodes.

6. The array substrate according to claim 5, further comprising second metallic nanoparticle layers located between the first electrodes and the electroluminescent function layers, wherein
the second metallic nanoparticle layers are configured to reflect the light exiting the electroluminescent function layers.

7. The array substrate according to claim 4, wherein the first electrodes are transparent electrodes, and the second electrodes are reflection electrodes.

8. The array substrate according to claim 7, further comprising third metallic nanoparticle layers located between the second electrodes and the electroluminescent function layers, wherein
the third metallic nanoparticle layers are configured to reflect the light exiting the electroluminescent function layers.

9. The array substrate according to claim 6, wherein material of the second metallic nanoparticle layers is the same as material of the first metallic nanoparticle layers.

10. A display device, comprising the array substrate according to claim 1.

11. A method for fabricating the array substrate according to claim 1, comprising:
forming the pixel defining layer on one side of the underlying substrate, wherein the pixel defining layer comprises the plurality of blocking walls arranged at intervals;
forming the first metallic nanoparticle layers on the side walls of the plurality of blocking walls; and
forming the electroluminescent function layers each located between two adjacent blocking walls of plurality of blocking walls, wherein the first metallic nanoparticle layers are located on the side walls of plurality of blocking walls proximate to the electroluminescent function layers, and are configured to reflect light exiting the electroluminescent function layers.

12. The method according to claim 11, wherein forming the first metallic nanoparticle layers on the side walls of the blocking walls comprises:
printing solution comprising first metallic nanoparticles onto the side walls of the blocking walls using an inkjet printing process to form the first metallic nanoparticle layers.

13. The method according to claim 11, wherein forming the first metallic nanoparticle layers on the side walls of the blocking walls comprises:
immersing the blocking walls of the pixel defining layer into solution comprising first metallic nanoparticles to form the first metallic nanoparticle layers, wherein the blocking walls are upside down when they are immersed into the solution.

14. The method according to claim 13, wherein for each of the blocking walls, a depth of a part of the blocking wall immersed into the solution is shallower than a depth of the blocking wall.

15. The method according to claim 11, wherein forming the pixel defining layer on one side of the underlying substrate, and forming the first metallic nanoparticle layers on the side walls of the blocking walls comprises:
forming a pixel defining layer film doped with first metallic nanoparticles on the underlying substrate; and
forming the pixel defining layer comprising the plurality of blocking walls arranged at intervals, and forming the first metallic nanoparticle layers on the side walls of the blocking walls, after the pixel defining layer film is exposed and developed.

16. The method according to claim 11, before the pixel defining layer is formed on one side of the underlying substrate, further comprising:
forming first electrodes on the underlying substrate; and
after the electroluminescent function layers are formed, further comprising:
forming second electrodes on the underlying substrate formed with the electroluminescent function layers.

17. The array substrate according to claim 8, wherein material of the third metallic nanoparticle layers is the same as the material of the first metallic nanoparticle layers.

18. The array substrate according to claim 2, further comprising:
first electrodes located between the electroluminescent function layers and the underlying substrate; and
second electrodes located on sides of the electroluminescent function layers away from the underlying substrate.

19. The array substrate according to claim 3, further comprising:
first electrodes located between the electroluminescent function layers and the underlying substrate; and
second electrodes located on sides of the electroluminescent function layers away from the underlying substrate.

20. The method according to claim 12, before the pixel defining layer is formed on one side of the underlying substrate, further comprising:
forming first electrodes on the underlying substrate; and
after the electroluminescent function layers are formed, further comprising:
forming second electrodes on the underlying substrate formed with the electroluminescent function layers.
